(19) United States
(12) Patent Application Publication
(10) Pub. No.: US 2021/0384227 A1
(43) Pub. Date: Dec. 9, 2021

(54) GATE-ALL-AROUND (GAA) TRANSISTOR WITH INSULATOR ON SUBSTRATE AND METHODS OF FABRICATING

(71) Applicant: QUALCOMM Incorporated, San Diego, CA (US)

(72) Inventors: Haining Yang, San Diego, CA (US); Bin Yang, San Diego, CA (US); Xia Li, San Diego, CA (US)

(21) Appl. No.: 16/895,835

(22) Filed: Jun. 8, 2020

(51) Int. Cl. H01L 27/12; H01L 29/423; H01L 29/06; H01L 29/10; H01L 29/08; H01L 29/04; H01L 21/84; H01L 21/02; H01L 21/306; H01L 21/762

(52) U.S. Cl. CPC H01L 27/1211; H01L 29/42392; H01L 29/0673; H01L 29/1037; H01L 21/76254; H01L 29/045; H01L 21/845; H01L 21/02532; H01L 21/30604; H01L 29/0847

(57) ABSTRACT

A gate-all-around (GAA) transistor has an insulator on a substrate. The GAA transistor also may have different crystalline structures for P-type work material and N-type work material. The GAA transistor includes one or more channels positioned between a source region and a drain region. The one or more channels, which may be nanowire, nanosheet, or nanoslab semiconductors, are surrounded along a longitudinal axis by gate material. At a first end of the channel is a source region and at an opposite end of the channel is a drain region. To reduce parasitic capacitance between a bottom gate section and a substrate, an insulator is added on the substrate. Further improvements are made in performance of a circuit having both P-type work material and N-type work material by providing different crystalline lattice structures for the work material.

### BACKGROUND

### I. Field of the Disclosure

The technology of the disclosure relates generally to transistors, and more particularly to gate-all-around (GAA) transistors and, more particularly, to limiting parasitic capacitance therein to improve performance.

### II. Background

Transistors are essential components in modern electronic devices. Large numbers of transistors are employed in integrated circuits (ICs) in many modern electronic devices. For example, components such as central processing units (CPUs), graphics processing units (GPUs), and memory systems each employ a large quantity of transistors for logic circuits and memory devices. There is a desire to reduce the size of individual transistors to conserve die area so that more computing power may be made available in devices of the same size. The pressure to reduce the size of transistors has led to the use of gate-all-around (GAA) transistors where a gate element surrounds a channel of the transistor. By providing a gate around the channel, control over the channel is improved, particularly for short channels, relative to other gate geometries. Further pressures to reduce size in such GAA transistors have caused the rise of parasitic capacitance, which may limit performance of the resulting transistor.

### SUMMARY OF THE DISCLOSURE

Aspects disclosed in the detailed description include a gate-all-around (GAA) transistor with an insulator on a substrate and methods of fabricating the same. Further, the GAA transistors may have different crystalline structures for P-type work material and N-type work material in the GAA transistor. The GAA transistor includes one or more channels positioned between a source region and a drain region. The one or more channels, which may be nanowire, nanosheet, or nanoslab semiconductors, are surrounded along a longitudinal axis by gate material. At a first end of the channel is a source region and at an opposite end of the channel is a drain region. To reduce parasitic capacitance between a bottom gate section and a substrate, an insulator is added on the substrate, which increases distances between conductive elements that form the parasitic capacitance. Further aspects include a circuit having both P-type work material and N-type work material by providing different crystalline lattice structures for the work material.

In this regard in one aspect, an integrated circuit (IC) is disclosed. The IC includes a substrate including a top surface. The IC also includes an insulator layer positioned adjacent to and above the top surface. The IC also includes a GAA transistor positioned on top of the insulator layer. The GAA transistor includes a bottom gate section positioned on top of the insulator layer. The GAA transistor also includes a nanostructure channel positioned on top of the bottom gate section. The nanostructure channel has a first end and a second end. The GAA transistor also includes a source region coupled to the nanostructure channel at the first end. The GAA transistor also includes a drain region coupled to the nanostructure channel at the second end.

In another aspect, an IC is disclosed. The IC includes a substrate including a top surface. The IC also includes a first GAA transistor positioned on the top surface. The first GAA transistor includes a first gate section. The first GAA transistor also includes a first channel including a first crystal orientation. The first channel is surrounded by the first gate section. The first GAA transistor also includes a first source at a first end portion of the first channel. The first GAA transistor also includes a first drain at a second end portion of the first channel. The IC also includes a second GAA transistor positioned on the top surface. The second GAA transistor a second gate section. The second GAA transistor also includes a second channel including a second crystal orientation different than the first crystal orientation. The second channel is surrounded by the second gate section. The second GAA transistor also includes a second source at a third end portion of the second channel. The second GAA transistor also includes a second drain at a fourth end portion of the second channel.

In another aspect, an IC is disclosed. The IC includes a substrate including a top surface. The IC also includes an insulator layer positioned adjacent to and above the top surface. The IC also includes a first GAA transistor positioned on the top surface. The first GAA transistor includes a first gate section. The first GAA transistor also includes a first channel surrounded by the first gate section. The first GAA transistor also includes a first source at a first end portion of the first channel. The first GAA transistor also includes a first drain at a second end portion of the first channel. The IC also includes a second GAA transistor positioned on the top surface. The second GAA transistor includes a second gate section. The second GAA transistor also includes a second channel surrounded by the second gate section. The second GAA transistor also includes a second source at a third end portion of the second channel. The second GAA transistor also includes a second drain at a fourth end portion of the second channel.

In another aspect, a method for fabricating an IC is disclosed. The method includes epitaxially growing a first set of alternating silicon (Si) and silicon germanium (SiGe) layers on a first wafer, wherein a first Si layer comprises a first crystal orientation. The method also includes etching through the first set of alternating Si and SiGe layers to create a cavity and expose the first wafer. The method also includes epitaxially growing a second set of alternating Si and SiGe layers on the first wafer in the cavity, wherein a second Si layer comprises a second crystal orientation different than the first crystal orientation. The method also includes bonding a substrate to a top layer of the first set of alternating Si and SiGe layers.

### BRIEF DESCRIPTION OF THE FIGURES

FIG. 1A is a perspective view of a conventional gate-all-around (GAA) transistor;

FIG. 1B is a cross-sectional side elevational view of the gate body of the GAA transistor of FIG. 1A;

FIG. 1C is a cross-sectional side elevational view of the gate body of the GAA transistor of FIGS. 1A and 1B taken along the line 1C-1C of FIG. 1B;

FIG. 2 is a top view of an exemplary circuit employing a plurality of GAA transistors including some that have a P-metal diffusion area and some that have an N-metal diffusion area;

FIG. 3A is a simplified top view of an exemplary circuit employing a P-metal GAA transistor and an N-metal GAA transistor with an insulator layer and different crystal orientations according to the present disclosure;

FIG. 3B is a side elevational cross-sectional view of the circuit of FIG. 3A taken along lines 3B-3B of FIG. 3A;

FIG. 4 is a flowchart illustrating an exemplary process for fabricating the circuit of FIGS. 3A and 3B;

FIGS. 5A-5L illustrate fabrication stages of the process steps of the process of FIG. 4;

FIG. 6 is a block diagram of an exemplary processor-based system that can include the circuit of FIGS. 3A and 3B; and

FIG. 7 is a block diagram of an exemplary wireless communications device that includes radio frequency (RF) components formed from an IC, wherein any of the components therein can include ICs that are formed according to the process of FIG. 4.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include a gate-all-around (GAA) transistor with an insulator on a substrate and methods of fabricating the same. Further, the GAA transistors may have different crystalline structures for P-type work material and N-type work material in the GAA transistor. The GAA transistor includes one or more channels positioned between a source region and a drain region. The one or more channels, which may be nanowire, nanosheet, or nanoslab semiconductors, are surrounded along a longitudinal axis by gate material. At a first end of the channel is a source region and at an opposite end of the channel is a drain region. To reduce parasitic capacitance between a bottom gate section and a substrate, an insulator is added on the substrate, which increases distances between conductive elements that form the parasitic capacitance. Further aspects include a circuit having both P-type work material and N-type work material by providing different crystalline lattice structures for the work material.

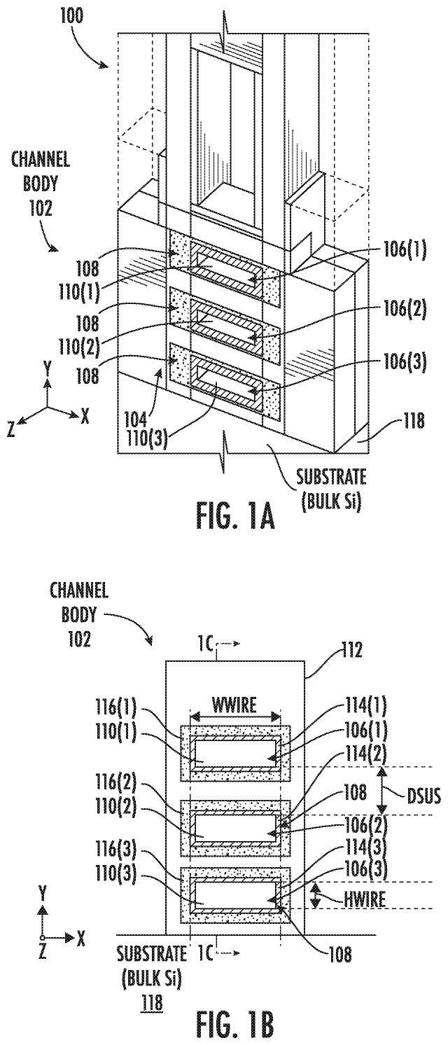

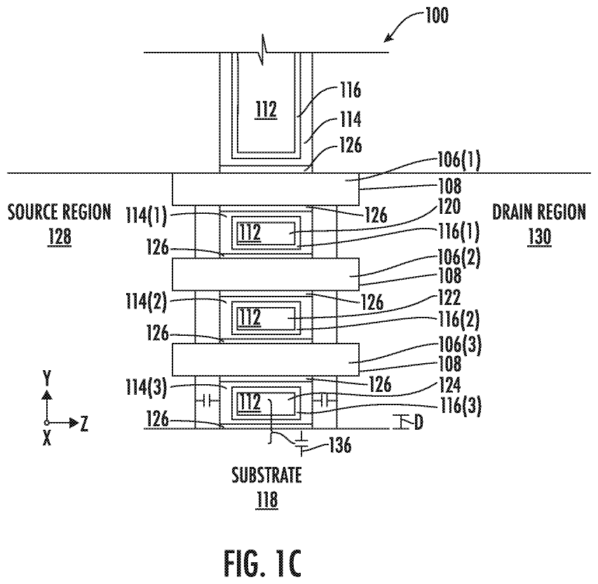

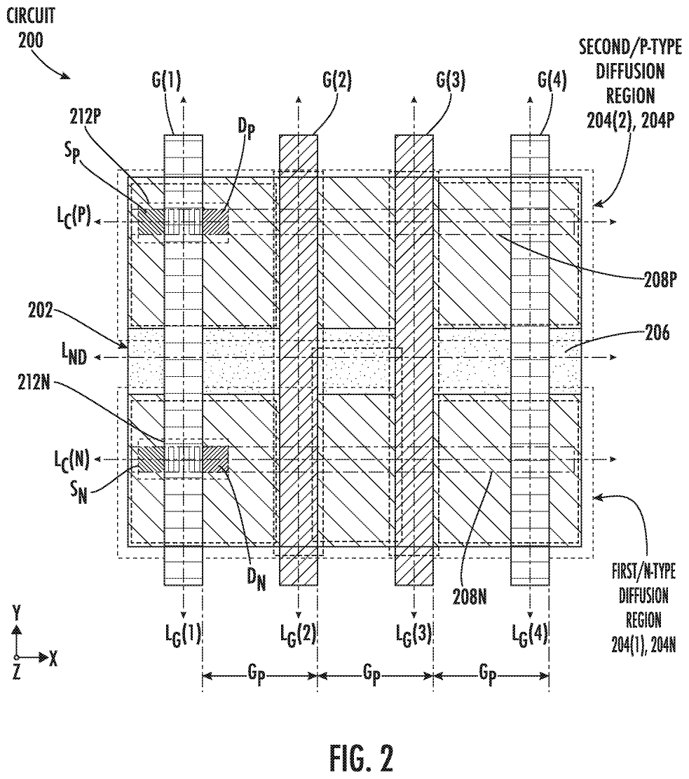

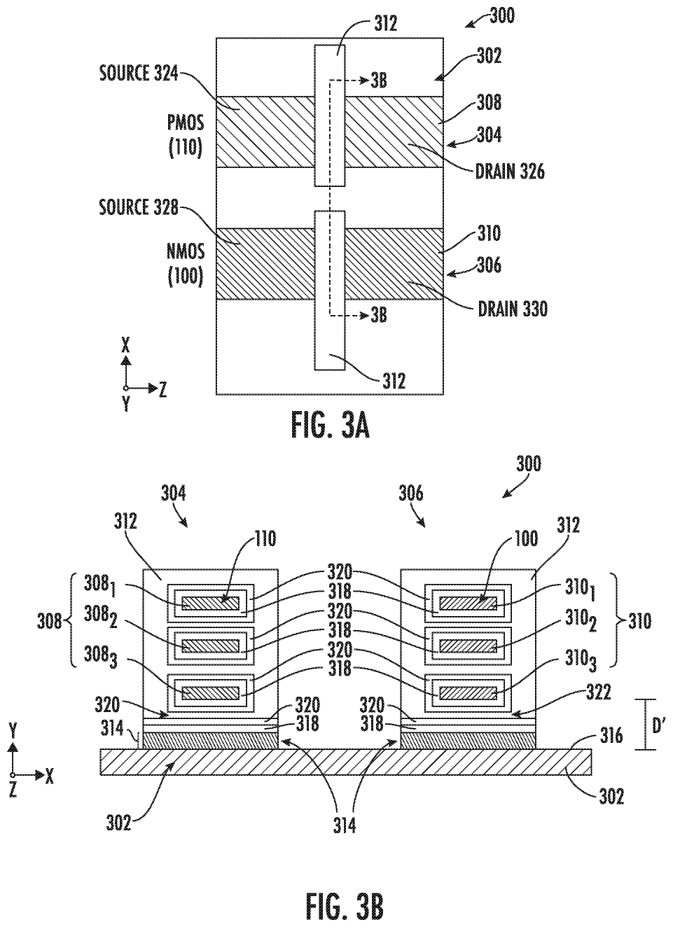

Before addressing particular aspects of the present disclosure, an overview of a conventional GAA transistor is provided with reference to FIGS. 1A-1C to highlight where parasitic capacitance may occur. Additional information about a standard cell circuit made with GAA transistors is provided in FIG. 2 showing how transistors with P-type work material and transistors with N-type work material may be placed in close proximity in a standard cell. Collectively FIGS. 1A-2 provide a point of context for the discussion of GAA transistors with an insulator layer and differing crystal orientations according to the present disclosure, which begins below with reference to FIG. 3A.

In this regard, FIGS. 1A and 1B illustrate perspective and side elevational views, respectively, of an exemplary transistor, which may be a field-effect transistor (FET) and, more specifically, is a nanowire GAA transistor 100. Note that while the GAA transistor 100 may be considered a GAA FET, it is referred to herein as just a GAA transistor. As shown in FIG. 1A, the GAA transistor 100 includes a channel body 102 that includes a nanowire channel structure 104 that includes a plurality of nanostructures 106(1)-106(3) that form a collective channel 108. The plurality of nanostructures 106(1)-106(3) are arranged in a vertically (i.e., along the Y-axis) stacked arrangement to increase channel current density for a given channel body 102 height, and thus increase the effective channel width for increased drive strength (i.e., drive current). In this example, the nanostructures 106(1)-106(3) are nanoslabs 110(1)-110(3) that are longer in the horizontal (X-axis) direction than they are tall in the vertical (Y-axis) direction.

FIG. 1B illustrates a side elevational view of the channel body 102 in the GAA transistor 100 in FIG. 1A. As shown in FIG. 1B, a gate material 112 in the form of a metal material completely surrounds the nanostructures 106(1)-106(3). An interfacial layer 114(1)-114(3) is disposed around the respective nanostructures 106(1)-106(3) followed by a high-K dielectric material layer 116(1)-116(3) to insulate the gate material 112 from the nanostructures 106(1)-106(3). Note that the interfacial layer 114(1)-114(3) and the high-K dielectric material layer 116(1)-116(3) are visible in FIG. 1A, but reference characters are omitted to avoid cluttering FIG. 1A. Applying a voltage to the gate material 112 controls an electric field in the nanostructures 106(1)-106(3) to cause current to flow through the nanostructures 106(1)-106(3) during an active mode.

The height (in the Y-axis) of each of the nanostructures 106(1)-106(3) is of a height Hwire in this example. Adjacent nanostructures 106(1)-106(3) are separated a distance Dsus from each other as shown in FIG. 1B. This distance Dsus is provided to allow the gate material 112 to be disposed completely around and between the adjacent nanostructures 106(1)-106(3) so that the gate material 112 can have greater electrostatic control of the collective channel 108 formed by the nanostructures 106(1)-106(3) of the GAA transistor 100. The distance Dsus may be fourteen (14) nanometers (nm) as an example in a conventional nanowire channel structure, such as the nanowire channel structure 104.

The channel body 102 may be formed on top of (i.e., in the Y-direction) a substrate 118 such as a bulk silicon (Si) body.

FIG. 1C is a cross-sectional view of the channel body 102 taken along line 1C-1C of FIG. 1B. Because of the change in orientation, the nanostructures 106(1)-106(3) forming the collective channel 108 now appear to sandwich the gate material 112 into a top gate section 120, middle gate section 122, and bottom gate section 124. While not illustrated in FIGS. 1A and 1B, the nanostructures 106(1)-106(3) abut insulating material 126, and the interfacial layers 114(1)-114(3) are positioned closer to the gate sections 120, 122, 124 than such insulating material 126. The high-K dielectric material layers 116(1)-116(3) are directly adjacent the gate material 112.

With continued reference to FIG. 1C, it is now possible to see source region 128 and drain region 130. While the source region 128 is shown as being on the left side (using the Z-axis) of the collective channel 108 and the drain region 130 is shown as being on the right side of the collective channel 108, it should be appreciated that these may be switched without substantially changing the operation of the GAA transistor 100.

Capacitance may occur between two conductive materials separated by a non-conducting material. When planar materials are considered, the capacitance can be calculated from the area A of the “plates” and the space (d) between the plates according to the well understood equation:

$$C = {ɛ}_{0} \frac{A}{d} \qquad Equation 1$$

where ε₀ is the electric constant (ε₀≈8.854×10⁻¹² F·m⁻¹). Accordingly, parasitic capacitance 136 may be formed between the bottom gate section 124 and the substrate 118. That is, the bottom gate section 124 may act as a first conductor and the substrate 118 may act as a second conductor, with capacitance therebetween as a function of the geometries of these bodies and the thickness of the dielectric materials between these bodies. This parasitic capacitance may negatively impact performance, contribute to unwanted power consumption, and/or contribute to increased leakage current.

The impact of the parasitic capacitance may be relatively benign for a single FET. However, single FETs rarely exist outside of a laboratory. Most ICs are made with hundreds if not thousands of FETs, usually arranged into standard cells from which logical blocks (e.g., inverters, adders, flip flops, etc.) may be formed. An exemplary circuit having multiple FETs is illustrated at FIG. 2.

In this regard, FIG. 2 illustrates an exemplary circuit 200 employing GAA transistors. FIG. 2 is a top down plan view of the circuit 200. The circuit 200 may be an integrated circuit (IC) that can be fabricated in an IC chip. The circuit 200 may be formed on a substrate 202, which may, in a typical IC chip, be a silicon substrate. The silicon substrate 202 may include a first diffusion region 204(1), which is an N-type diffusion region 204(1) (also labeled “204N”) and a second diffusion region 204(2), which is a P-type diffusion region 204(2) (also labeled “204P”). For example, the N-type diffusion region 204N may be formed by doping a portion of the substrate 202 with a pentavalent impurity material as a donor material that is able to give up free electrons in the substrate 202. Likewise as an example, the P-type diffusion region 204P may be formed by doping a portion of the substrate 202 with an impurity material that is able to leave holes in the substrate 202.

The substrate 202 may include one or more diffusion breaks that provide isolation to impede the flow electrons or holes between different semiconductor channels of FETs or other semiconductor devices formed on different sides of the diffusion breaks in the X-axis direction. For example, diffusion breaks may be included in the circuit 200 if a circuit design calls for a different bias voltage to be applied to different semiconductor devices formed in the circuit requiring isolation. Also note that there is a non-diffusion region 206 having a longitudinal axis L_{ND} in the X-axis direction between the P-type diffusion region 204P and the N-type diffusion region 204N in the circuit 200.

As shown in FIG. 2, N-type and P-type semiconductor channels 208N, 208P are formed in the circuit 200 above the substrate 202 and extended along longitudinal axes L_{C}(N), L_{C}(P) in the X-axis direction. It should be appreciates that channels 208N, 208P may be a stack of nanostructures such as the nanostructures 106(1)-106(3) of FIGS. 1A-1C. Gates G(1)-G(4) are formed in the circuit 200 along longitudinal axes L_{G}(1)-L_{G}(4) in the Y-axis direction, orthogonal to the longitudinal axes L_{C}(N), L_{C}(P) of the N-type and P-type semiconductor channels 208N, 208P, and extend above and around at least a portion of the P-type and N-type semiconductor channels 208N, 208P. Gates G1(1)-G(4) are separated laterally from adjacent ones of each other (in the X-axis direction) by a pitch distance, labeled here G_{P}.

As shown in FIG. 2, a three dimensional (3D) N-type metal oxide semiconductor (MOS) FET (NFET or NMOS) 212N in the form of a GAA FET in this example is formed in the N-type diffusion region 204N by forming a source S_{N} and drain D_{N} on opposites sides of the active gate G(1) in the N-type diffusion region 204N. Similarly, as shown in FIG. 2, a 3D P-type metal oxide semiconductor (MOS) FET (PFET or PMOS) 212P also in the form of a GAA FET in this example is formed in the P-type diffusion region 204P by forming a source S_{P} and drain D_{P} on opposites sides of the active gate G(1) in the P-type diffusion region 204P.

In traditional manufacturing techniques, the crystal orientation, as defined by the Miller Indices, of the substrate 202 and the diffusion regions 204(1) and 204(2) as well as the channels 208N and 208P may be identical. However, it has been noted that different crystal orientations may affect electron and hole mobility differently. Thus, if a single crystal orientation is used for both the N-type material and for the P-type material, one material is likely to have sub-optimal performance.

Exemplary aspects of the present disclosure provide a GAA transistor that reduces the parasitic capacitance 136 of FIGS. 1A-1C by increasing the “d” of Equation 1 by adding an insulator layer between the substrate and the bottom gate section. The increase in “d” in Equation 1 reduces the capacitance generated between the bottom gate section and the substrate. Further, the insulator material may help reduce possible capacitance formed between the source region and the substrate or the drain region and the substrate. The reduction in capacitance improves performance.

Still further exemplary aspects of the present disclosure form the crystal lattice of the N-type material separately from the crystal lattice of the P-type material. The lattices are formed separately so that different crystalline orientations are made. Specifically, the work material for the PMOS may have a crystal orientation of (110) while the work material for the NMOS may have a crystal orientation of (100) as defined by the Miller Indices. By having different orientations, electron and hole mobility are optimized for the respective work functions instead of having to use the same orientation for both where one or the other of the electron or hole mobility would be suboptimal.

In this regard, FIG. 3A illustrates a simplified circuit 300 having a substrate 302 on which a PMOS transistor 304 and an NMOS transistor 306 are formed. In an exemplary aspect, the substrate 302 lies in a plane defined by the X-axis and the Z-axis. The PMOS transistor 304 includes a channel stack 308 formed of a plurality of nanostructure channels positioned one over the other (e.g., over a bottom channel) with a first crystal orientation, which, in an exemplary aspect, may be (110) as defined by the Miller Indices. The NMOS transistor 306 includes a channel stack 310 formed of a plurality nanostructure channels positioned one over the other (e.g., over a bottom channel) with a second crystal orientation, which, in an exemplary aspect, may be (100) as defined by the Miller Indices. A gate material 312 may surround the channel stack 308 and the channel stack 310 as better seen in FIG. 3B.

FIG. 3B is a cross-sectional elevational view of the circuit 300 taken along lines 3B-3B of FIG. 3A. An insulator layer 314 may be positioned adjacent to and on a top (relative to the Y-axis) surface 316 of the substrate 302. The insulator layer 314 may be made from an insulating material such as a semiconductor oxide such as silicon dioxide (SiO₂) and may have a thickness 314T (along the Y-axis) of 50 nm. The individual nanostructures 308₁-308₃ within the channel stack 308 may be surrounded by an interfacial material 318, which in turn is surrounded by a high-K dielectric material 320. Similarly, the individual nanostructures 310₁-310₃ may be surrounded by the interfacial material 318, which in turn is surrounded by the high-K dielectric material 320. An additional layer of the interfacial material 318 and an additional layer of the high-K dielectric material 320 may be positioned between the bottom section 322 of the gate material 312 and the insulator layer 314.

By adding the insulator layer 314 between the bottom section 322 of the gate material 312 and the substrate 302, d′ is relatively large compared to d of FIG. 1C, and thus, C as determined by Equation 1 is reduced. Thus, introduction of the insulator layer 314 reduces the parasitic capacitance found in the conventional GAA transistor 100.

It should be appreciated that a source region 324 (sometimes just referred to as a source) is positioned at a first end portion of the channel stack 308 while a drain region 326 (sometimes just referred to as a drain) is positioned at a second end portion of the channel stack 308. Likewise, a source region 328 (sometimes just referred to as a source) is positioned at a first end portion of the channel stack 310 and a drain region 330 (sometimes just referred to as a drain) is positioned at a second end portion of the channel stack 310.

Further, by changing the crystal orientation (as defined by the Miller Indices) between the PMOS transistor 304 and the NMOS transistor 306, the respective hole and electron mobilities are optimized. Such optimization of the hole and electron mobilities improves channel performance and thus device performance.

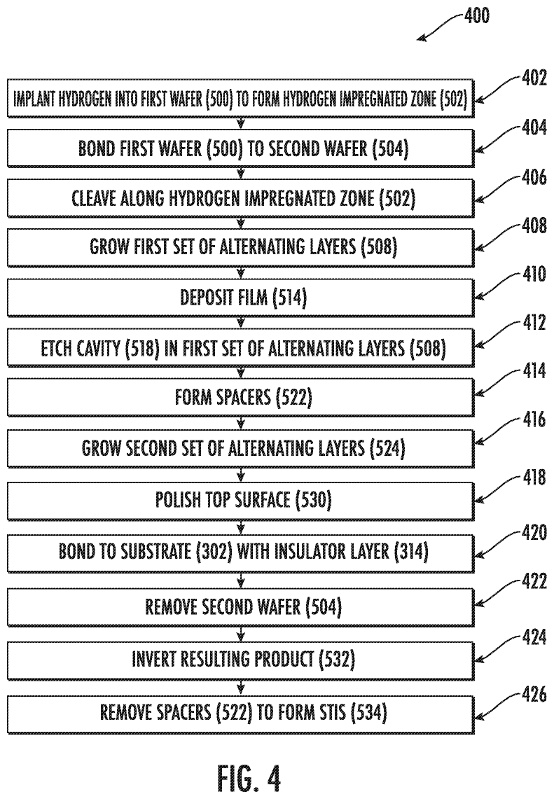

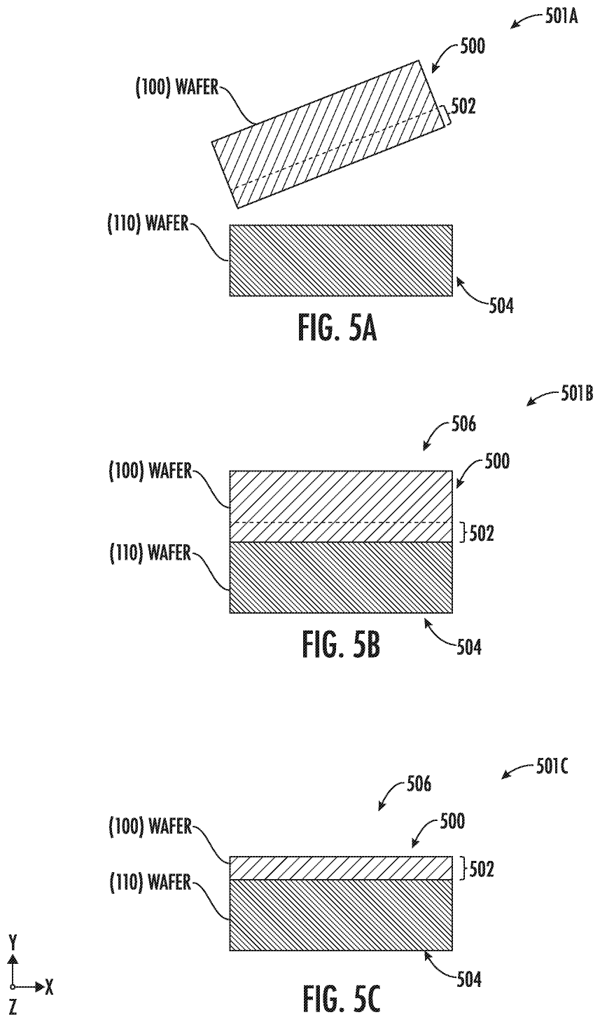

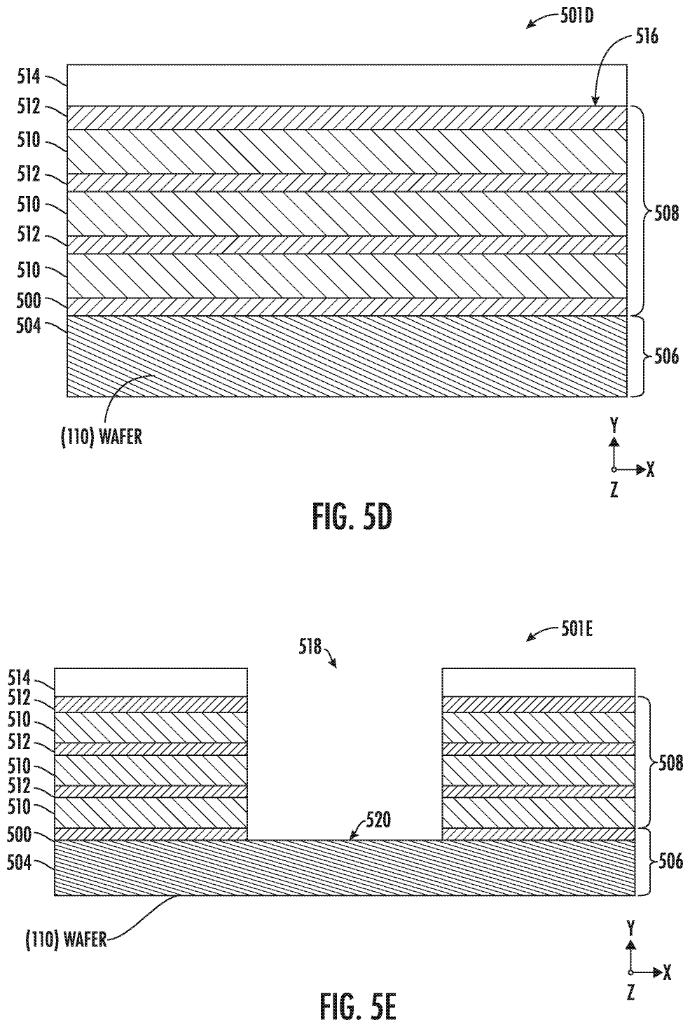

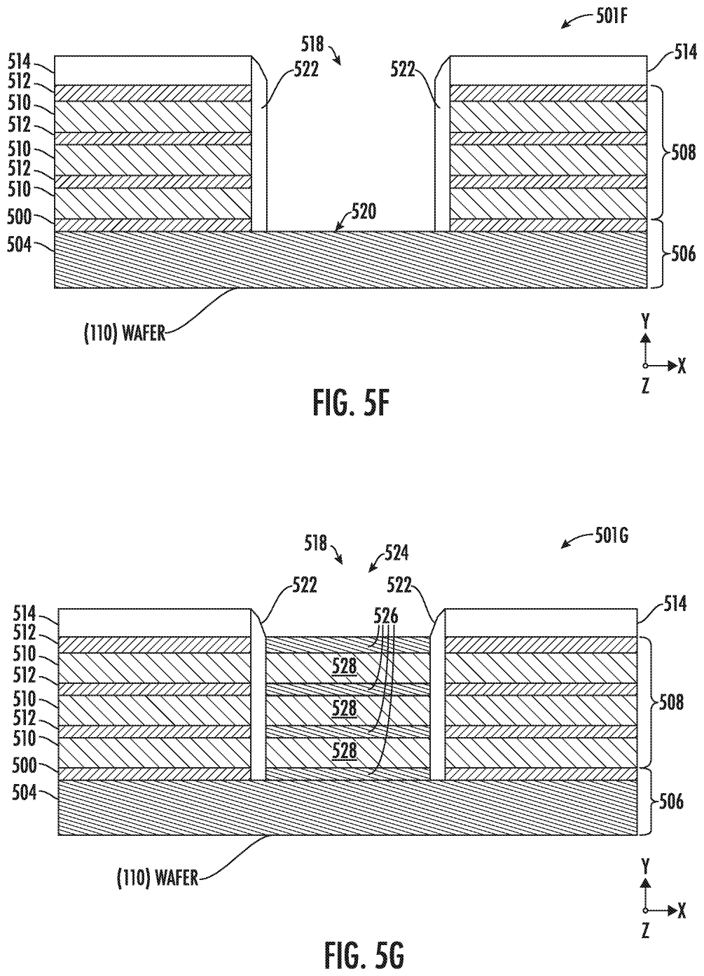

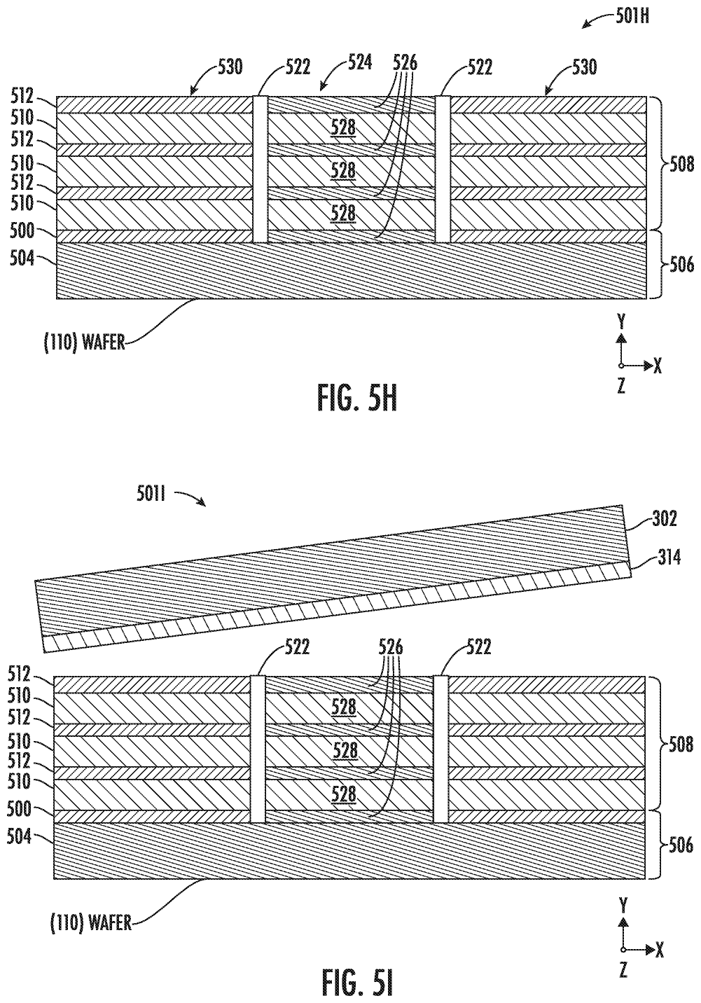

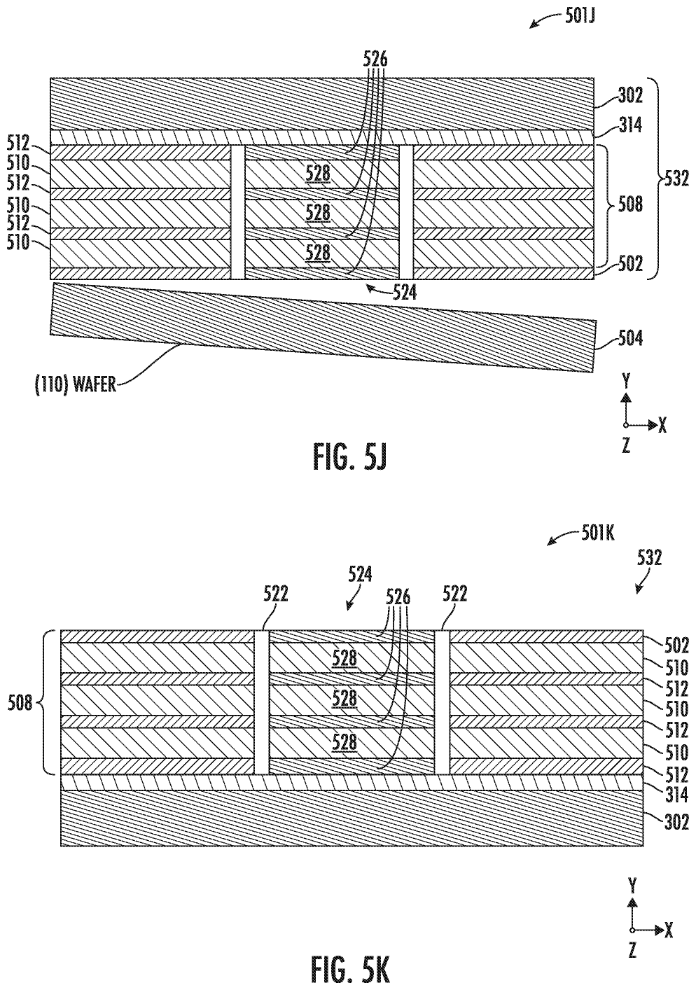

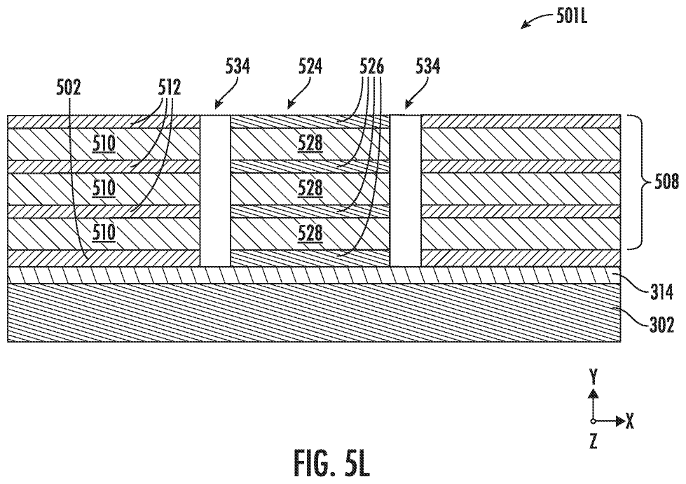

A process 400 to fabricate the circuit 300 having the insulator layer 314 and different crystal orientations is set forth as a flowchart in FIG. 4 with reference to FIGS. 5A-5L to illustrate individual steps or fabrication stages. In this regard, the process 400 begins by implanting hydrogen into a first wafer 500 to form a hydrogen impregnated zone 502 (block 402, see fabrication stage 501A of FIG. 5A). Note that the first wafer 500 may have a first crystal orientation of (100) as defined by the Miller Indices. The first wafer 500 is then bonded to a second wafer 504 (block 404) to form temporary wafer 506 (see fabrication stage 501B of FIG. 5B). Note that the second wafer 504 may have a second crystal orientation of (110) as defined by the Miller Indices. The first wafer 500 is then cleaved along the hydrogen impregnated zone 502 (block 406, see fabrication stage 501C FIG. 5C). Note that the implantation of hydrogen ions into the first wafer 500 makes such cleaving relatively simple. Alternatively, instead of implantation and cleaving, the temporary wafer 506 may undergo a polishing step to reduce the size of the first wafer 500.

The process 400 continues by growing a first set of alternating layers 508 (block 408) on the temporary wafer 506 of fabrication stage 501D as shown in FIG. 5D. The first set of alternating layers 508 may be grown epitaxially and may be alternating layers of silicon germanium (SiGe) 510 and layers of silicon (Si) 512. Note that the layers of silicon 512 may have the first crystal orientation. The layers of silicon 512 along with the residual material of the hydrogen impregnated zone 502 may form the channels of the transistors being created. The layers of SiGe 510 may be sacrificial layers that are removed in a later step to be replaced by gate material 312. After formation of the first set of alternating layers 508, a film 514 is deposited (block 410) on a top surface 516 of the first set of alternating layers 508. In an exemplary aspect, the film 514 is a silicon nitride (Si₃N₄) film

The process 400 continues by etching a cavity 518 in the first set of alternating layers 508 (block 412, see fabrication stage 501E of FIG. 5E). Note that the cavity 518 is etched deep enough to expose a top surface 520 of the second wafer 504. Spacers 522 are then formed (block 414, see fabrication stage 501F of FIG. 5F). The spacers 522 may be formed through deposition of a Si₃N₄ film.

The process 400 continues by growing a second set of alternating layers 524 (block 416) between the spacers 522 filling the cavity 518 as shown by fabrication stage 501G in FIG. 5G. In an exemplary aspect, the second set of alternating layers 524 may also be alternating layers of silicon 526 and layers of SiGe 528. In an exemplary aspect, the layers of silicon 526 may have the second crystal orientation. Again, the layers of silicon 526 may form the channels and the layers of SiGe 528 may be sacrificial for gate formation.

The process 400 continues by polishing a top surface 530 (block 418) to remove the film 514 as shown by fabrication stage 501H in FIG. 5H. The polishing may be a chemical mechanical polish (CMP) or other form of planarization as needed or desired. The top surface 530 of the top layer of the alternating layers is then bonded to the substrate 302 with the insulator layer 314 (block 420, see fabrication stage 501I of FIG. 5I). In an exemplary aspect, the insulator layer 314 is substantially coextensive with the substrate 302. That is, the insulator layer 314 has substantially the same planar dimensions as the top surface of the substrate 302. As used herein, “substantially” means within five percent (5%). In another exemplary aspect, the insulator layer 314 is only positioned underneath the gate stack (see FIG. 3B).

The process 400 continues by removing the second wafer 504 (block 422, see fabrication stage 501J of FIG. 5J) and inverting the resulting product 532 (block 424, see fabrication stage 501K of FIG. 5K). The spacers 522 are then removed and shallow trench isolations (STIs) 534 are formed (block 426) as shown by fabrication stage 501L in FIG. 5L. The spacers 522 may be removed by etching or other conventional technique.

While not shown, the sacrificial layers of SiGe 510 and 528 may be removed and gate material 312 flowed into the cavities so formed along with interfacial material 318 and high-K dielectric material 320 as is well understood.

The GAA transistor with an insulator on a substrate and methods of fabricating according to aspects disclosed herein may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

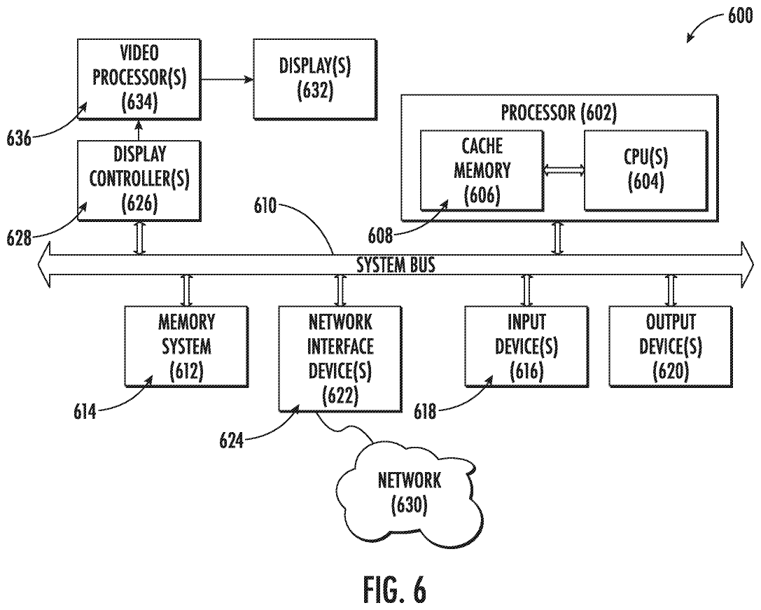

In this regard, FIG. 6 illustrates an example of a processor-based system 600 that can include GAA transistors 300 such as that illustrated in FIGS. 3A and 3B. In this example, the processor-based system 600 includes a processor 602 that includes one or more CPUs 604. The processor 602 may have cache memory 606 coupled to the CPU(s) 604 for rapid access to temporarily stored data. The cache memory 606 may include GAA transistors 608 such as the GAA transistor 200. The processor 602 is coupled to a system bus 610 and can intercouple master and slave devices included in the processor-based system 600. As is well known, the processor 602 communicates with these other devices by exchanging address, control, and data information over the system bus 610. Although not illustrated in FIG. 6, multiple system buses 610 could be provided, wherein each system bus 610 constitutes a different fabric. For example, the processor 602 can communicate bus transaction requests to a memory system 612 as an example of a slave device. The memory system 612 may include memory structures or arrays that include GAA transistors 614.

Other master and slave devices can be connected to the system bus 610. As illustrated in FIG. 6, these devices can include the memory system 612 and one or more input devices 616, which can include GAA transistors 618. The input device(s) 616 can include any type of input device, including, but not limited to, input keys, switches, voice processors, etc. These devices can also include one or more output devices 620 and one or more network interface devices 622, which can include GAA transistors 624. The output device(s) 620 can include any type of output device, including, but not limited to, audio, video, other visual indicators, etc. These devices can also include one or more display controllers 626, including GAA transistors 628. The network interface device(s) 622 can be any devices configured to allow exchange of data to and from a network 630. The network 630 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 622 can be configured to support any type of communications protocol desired.

The processor 602 may also be configured to access the display controller(s) 626 over the system bus 610 to control information sent to one or more displays 632. The display controller(s) 626 sends information to the display(s) 632 to be displayed via one or more video processors 634, which process the information to be displayed into a format suitable for the display(s) 632. The video processor(s) 634 can include GAA transistors 636. The display(s) 632 can include any type of display, including, but not limited to, a cathode ray tube (CRT), a liquid crystal display (LCD), a plasma display, a light emitting diode (LED) display, etc.

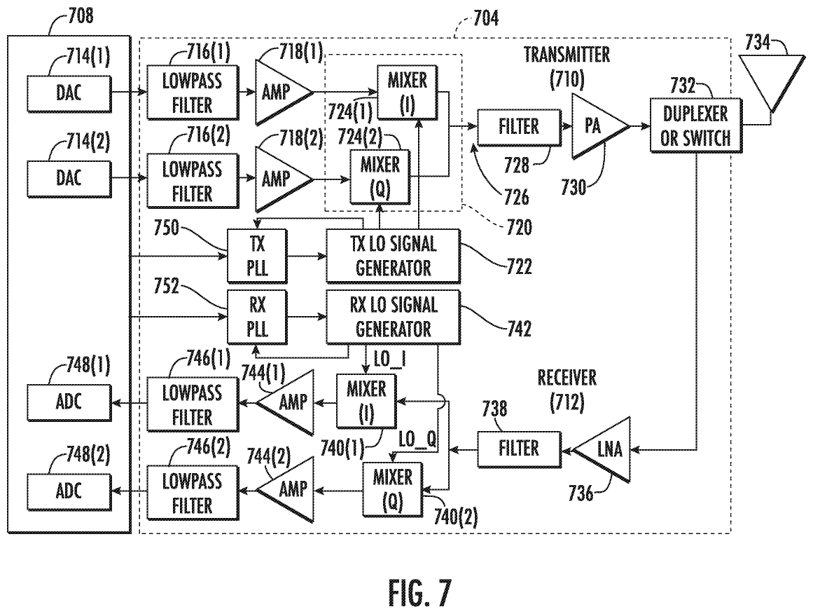

FIG. 7 illustrates an example of a wireless communications device 700 which can include RF components with GAA transistor 300. The wireless communications device 700 may include or be provided in any of the above-referenced devices, as examples. As shown in FIG. 7, the wireless communications device 700 includes a transceiver 704 and a data processor 708. The data processor 708 may include a memory (not shown) to store data and program codes. The transceiver 704 includes a transmitter 710 and a receiver 712 that support bi-directional communication. In general, the wireless communications device 700 may include any number of transmitters and/or receivers for any number of communication systems and frequency bands. All or a portion of the transceiver 704 may be implemented on one or more analog ICs, RF ICs (RFICs), mixed-signal ICs, etc.

A transmitter 710 or a receiver 712 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for a receiver 712. In the direct-conversion architecture, a signal is frequency converted between RF and baseband in one stage. The super-heterodyne and direct-conversion architectures may use different circuit blocks and/or have different requirements. In the wireless communications device 700 in FIG. 7, the transmitter 710 and the receiver 712 are implemented with the direct-conversion architecture.

In the transmit path, the data processor 708 processes data to be transmitted and provides I and Q analog output signals to the transmitter 710. In the exemplary wireless communications device 700, the data processor 708 includes digital-to-analog-converters (DACs) 714(1) and 714(2) for converting digital signals generated by the data processor 708 into the I and Q analog output signals, e.g., I and Q output currents, for further processing.

Within the transmitter 710, lowpass filters 716(1), 716(2) filter the I and Q analog output signals, respectively, to remove undesired images caused by the prior digital-to-analog conversion. Amplifiers (AMPs) 718(1), 718(2) amplify the signals from the lowpass filters 716(1), 716(2), respectively, and provide I and Q baseband signals. An upconverter 720 upconverts the I and Q baseband signals with I and Q transmit (TX) local oscillator (LO) signals through mixers 724(1), 724(2) from a TX LO signal generator 722 to provide an upconverted signal 726. A filter 728 filters the upconverted signal 726 to remove undesired images caused by the frequency upconversion as well as noise in a receive frequency band. A power amplifier (PA) 730 amplifies the upconverted signal 726 from the filter 728 to obtain the desired output power level and provides a transmit RF signal. The transmit RF signal is routed through a duplexer or switch 732 and transmitted via an antenna 734.

In the receive path, the antenna 734 receives signals transmitted by base stations and provides a received RF signal, which is routed through the duplexer or switch 732 and provided to a low noise amplifier (LNA) 736. The duplexer or switch 732 is designed to operate with a specific RX-to-TX duplexer frequency separation, such that RX signals are isolated from TX signals. The received RF signal is amplified by the LNA 736 and filtered by a filter 738 to obtain a desired RF input signal. Downconversion mixers 740(1), 740(2) mix an output of the filter 738 with I and Q receive (RX) LO signals (i.e., LO_I and LO_Q) from an RX LO signal generator 742 to generate I and Q baseband signals. The I and Q baseband signals are amplified by AMPs 744(1), 744(2) and further filtered by lowpass filters 746(1), 746(2) to obtain I and Q analog input signals, which are provided to the data processor 708. In this example, the data processor 708 includes analog-to-digital-converters (ADCs) 748(1), 748(2) for converting the analog input signals into digital signals to be further processed by the data processor 708.

In the wireless communications device 700 in FIG. 7, the TX LO signal generator 722 generates the I and Q TX LO signals used for frequency upconversion, while the RX LO signal generator 742 generates the I and Q RX LO signals used for frequency downconversion. Each LO signal is a periodic signal with a particular fundamental frequency. A transmit (TX) phase-locked loop (PLL) circuit 750 receives timing information from data processor 708 and generates a control signal used to adjust the frequency and/or phase of the TX LO signals from the TX LO signal generator 722. Similarly, a receive (RX) phase-locked loop (PLL) circuit 752 receives timing information from the data processor 708 and generates a control signal used to adjust the frequency and/or phase of the RX LO signals from the RX LO signal generator 742.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. The devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

1. An integrated circuit (IC), comprising:
a substrate comprising a top surface;
an insulator layer positioned adjacent to and above the top surface; and
a gate-all-around (GAA) transistor positioned on top of the insulator layer, the GAA transistor comprising:
a bottom gate section positioned on top of the insulator layer;
a nanostructure channel positioned on top of the bottom gate section, the nanostructure channel having a first end and a second end;
a source region coupled to the nanostructure channel at the first end; and
a drain region coupled to the nanostructure channel at the second end.

2. The IC of claim 1, wherein the substrate comprises a bulk silicon substrate.

3. The IC of claim 1, wherein the insulator layer comprises a silicon dioxide material.

4. The IC of claim 1, wherein the nanostructure channel has a crystal orientation of (110) as defined by the Miller Indices.

5. The IC of claim 1, wherein the nanostructure channel has a crystal orientation of (100) as defined by the Miller Indices.

6. The IC of claim 1, further comprising a second gate section positioned above the nanostructure channel.

7. The IC of claim 1, wherein the insulator layer is substantially coextensive with the substrate.

8. The IC of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

9. An integrated circuit (IC), comprising:
a substrate comprising a top surface;
a first gate-all-around (GAA) transistor positioned on the top surface, the first GAA transistor comprising:
a first gate section;
a first channel comprising a first crystal orientation, the first channel surrounded by the first gate section;
a first source at a first end portion of the first channel; and
a first drain at a second end portion of the first channel; and
a second GAA transistor positioned on the top surface, the second GAA transistor comprising:
a second gate section;
a second channel comprising a second crystal orientation different than the first crystal orientation, the second channel surrounded by the second gate section;
a second source at a third end portion of the second channel; and
a second drain at a fourth end portion of the second channel.

10. The IC of claim 9, wherein the first crystal orientation comprises a (100) crystal orientation as defined by the Miller Indices.

11. The IC of claim 9, wherein the second crystal orientation comprises a (110) crystal orientation as defined by the Miller Indices.

12. The IC of claim 9, further comprising an insulator layer positioned on the top surface between the top surface and the first gate section.

13. The IC of claim 9, wherein the first channel comprises a nanostructure.

14. The IC of claim 13, wherein the nanostructure is selected from the group consisting of: a nanowire, a nanoslab, and a nanosheet.

15. The IC of claim 9, further comprising a plurality of channels positioned over the first channel to form a channel stack.

16. The IC of claim 9, further comprising an interfacial layer and a high-K dielectric material surrounding the first channel and in between the first channel and the first gate section.

17. The IC of claim 12, wherein the insulator layer is substantially coextensive with the top surface.

18. The IC of claim 9 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

19. An integrated circuit (IC), comprising:
a substrate comprising a top surface;
an insulator layer positioned adjacent to and above the top surface; and
a first gate-all-around (GAA) transistor positioned on the top surface, the first GAA transistor comprising:
a first gate section;
a first channel surrounded by the first gate section;
a first source at a first end portion of the first channel; and
a first drain at a second end portion of the first channel; and
a second GAA transistor positioned on the top surface, the second GAA transistor comprising:
a second gate section;
a second channel surrounded by the second gate section;
a second source at a third end portion of the second channel; and
a second drain at a fourth end portion of the second channel.

20-28. (canceled)
